(19) United States
(12) Patent Application Publication
(10) Pub. No.: US 2012/0241768 A1
(43) Pub. Date: Sep. 27, 2012

(54) OPTICAL SENSOR CIRCUIT, DISPLAY PANEL, DISPLAY DEVICE, AND METHOD FOR DRIVING AN OPTICAL SENSOR CIRCUIT

(75) Inventors: Atsuhito Murai, Osaka-shi (JP); Kazunori Morimoto, Osaka-shi (JP); Yukihiko Nishiyama, Osaka-shi (JP); Hajime Imai, Osaka-shi (JP); Hideki Kitagawa, Osaka-shi (JP)

(73) Assignee: SHARP KABUSHIKI KAISHA, Osaka-shi, Osaka (JP)

(21) Appl. No.: 13/508,045

(22) PCT Filed: Jun. 25, 2010
(86) PCT No.: PCT/JP2010/060863

§ 371 Date: Jun. 8, 2012

(30) Foreign Application Priority Data
Nov. 12, 2009 (JP) 2009-259248

(51) Int. Cl. H01L 27/146; H01L 31/113

(52) U.S. Cl. 257/84; 257/290; 250/214.1; 257/E31.083; 257/E27.132

(57) ABSTRACT

An optical sensor circuit (20) includes a transistor (20c) and a transistor (20d). The transistor (20c) is connected in series with the transistor (20d). The transistor (20d) is configured to receive light. A black matrix is provided so as to face the transistor (20c). A voltage generated at a connecting point (i.e., node (netB)) of the transistor (20d) and the transistor (20c) varies depending on intensity of light received via the transistor (20d).

### TECHNICAL FIELD

The present invention relates to (i) an optical sensor circuit, (ii) a display panel including the optical sensor circuit, (iii) a display device, and (iv) a method for driving an optical sensor circuit.

### BACKGROUND ART

A liquid crystal display device has been known in which an optical sensor circuit is included in a picture element or a pixel.

For example, the following description will discuss, with reference to FIG. 11, a configuration of a liquid crystal display device (disclosed in Patent Literature 1) which includes an optical sensor circuit.

FIG. 11 is an equivalent circuit diagram illustrating the liquid crystal display panel disclosed in Patent Literature 1.

FIG. 11 illustrates a configuration of an extracted n-th row in a display area of the liquid crystal display panel. According to the configuration of the n-th row, (i) a plurality of picture elements PIX are defined by a gate line Gn, source lines S (in FIG. 11, source lines Sm through Sm+3), and a retention capacitor line Csn and (ii) at least one optical sensor circuit 100 is provided which is connected with a reset line Vrstn and a readout control line Vrwn. Note that the symbol “n” at the end of each reference symbol indicates a row number, and the symbol “m” at the end of each reference symbol indicates a column number.

Each of the plurality of picture elements PIX includes (i) a TFT 101 serving as a selection element, (ii) a liquid crystal capacitor CL, and (iii) a retention capacitor CS. The TFT 101 has (i) a gate connected with the gate line Gn, (ii) a source connected with the source line S, and (iii) a drain connected with a picture element electrode 102. The liquid crystal capacitor CL is a capacitor defined by the picture element electrode 102 and a common electrode Com between which a liquid crystal layer is provided. The retention capacitor CS is a capacitor defined by (i) the picture element electrode 102 or the drain electrode of the TFT 101 and (ii) the retention capacitor line Csn, between which an insulating film is provided. For example, constant voltages are applied to respective of the common electrode Com and the retention capacitor line Csn.

The number of the optical sensor circuit(s) 100 is set arbitrarily. That is, the optical sensor circuit 100 can be provided (i) for each picture element PIX or (ii) for each pixel made up of, for example, a set of three picture elements PIX of respective R, G, and B. The optical sensor circuit 100 includes a TFT 100a, a capacitor 100b, and a photodiode 100c. The TFT 100a has (i) a gate connected with an electrode referred to as “node netA”, (ii) a drain connected with a source line S (here, the source line Sm), and (iii) a source connected with another source line S (here, the source line Sm+1). The photodiode 100c has (i) an anode connected with the reset line Vrstn and (ii) a cathode connected with the node netA. One end of the capacitor 100b is connected with the node netA, and the other end of the capacitor 100b is connected with the readout control line Vrwn.

The optical sensor circuit 100 is configured so as to (i) output, as a sensor output voltage Vom from the source of the TFT 100a during a period other than a period in which a data signal is written into a picture element PIX, an output voltage which is generated at the node netA in accordance with the intensity of light received via the photodiode 100c and (ii) supply, via the source line S (which serves as a sensor output line Vom (for convenience, the same reference symbol is given to the sensor output voltage and the sensor output line) during a light detection) connected with the source of the TFT 100a, the output voltage to the sensor readout circuit (not illustrated) provided outside of the display area. At this time, the TFT 100a serves as a source follower. Moreover, during light detection, the source line S connected with the drain of the TFT 100a serves as a power supply line Vsm to which a constant voltage is applied.

Here, the source lines S serve as respective of the optical sensor output line Vom and the power supply line Vsm. With the configuration, readout from the optical sensor circuit 100 is carried out only during a retrace period. In a case where the retrace period becomes short due to high resolution (VGA, XGA, etc.) in display, there occurs a problem that it is difficult to employ a configuration in which one line serves more than one function.

In order to solve the problem, each of the sensor output line Vom and the power supply line Vsm can be provided as a line which is separated from a corresponding one of the source lines S, as indicated in FIG. 11 by dotted lines in the vicinity of the respective source lines S.

The following description will discuss, in detail, how the optical sensor circuit 100 operates, with reference to FIG. 12. Specifically, the following description will discuss a case where, for example, an n-ch semiconductor is used as each of a TFT and a photodiode.

FIG. 12 is a waveform chart for explaining how the optical sensor circuit 100 operates.

During a period in which data signals are written, (i) a gate pulse, which has a High level (e.g., +21 V) and a Low level (e.g., −10 V), is supplied as a scanning signal to the gate line Gn and (ii) data signals are supplied to the respective source lines S. A constant voltage of, for example, +4 V is applied to the retention capacitor line Csn. These operations are carried out with respect to picture elements PIX in each row for every vertical period (1V). During a period other than the period in which the data signals are written, results of light detection carried out by the optical sensor circuit 100 can be supplied to the sensor readout circuit.

During a period (1) illustrated in FIG. 12, in a case where a reset pulse Prstn, which has a High level (e.g., −4 V) and a Low level (e.g., −16 V), is applied from the external sensor readout circuit to the reset line Vrstn, the photodiode 100c becomes conductive in a forward direction, and a voltage at the node netA is reset to a voltage of the reset line Vrstn.

Subsequently, during a period (2) illustrated in FIG. 12, a leakage is caused in the photodiode 100c, which is in a reverse bias state, in accordance with intensity of light received via the photodiode 100c. This causes the voltage at the node netA to be decreased in proportion to the intensity of the light.

During a period (3) illustrated in FIG. 12, in a case where a readout pulse Prwn, having a High level (e.g., +21 V) and a Low level (e.g., −10 V), is supplied from the sensor readout circuit to the readout control line Vrwn, the voltage at the node netA is increased. At this time, the voltage at the node netA is set to reach a range higher than a threshold voltage of the TFT 100a. Note that the sensor output voltage Vom, which is supplied from the source of the TFT 100a during the readout pulse Prwn is being applied, is a voltage corresponding to a node netA voltage, that is, corresponding to a voltage which varies depending on light intensity. It is therefore possible to detect the light intensity by reading out, via the sensor output line Vom, the sensor output voltage Vom by use of the sensor readout circuit.

During a period (4) illustrated in FIG. 12, the outputting of the sensor output voltage is ended, and the optical sensor circuit 100 stops operating until a next resetting operation.

During a period (5) illustrated in FIG. 12, a reset pulse Prstn is applied again from the external sensor readout circuit to the reset line Vrstn, and therefore the photodiode 100c becomes conductive in the forward direction. This causes the voltage at the node netA to be reset to the voltage of the reset line Vrstn.

Subsequently, during a period (6) illustrated in FIG. 12, a leakage is caused in the photodiode 100c, which is in a reverse bias state, in accordance with intensity of light received via the photodiode 100c. This causes the voltage at the node netA to be decreased in proportion to the intensity of the light.

During a period (7) illustrated in FIG. 12, in a case where a readout pulse Prwn, having a High level (e.g., +21 V) and a Low level (e.g., −10 V), is supplied from the sensor readout circuit to the readout control line Vrwn, the voltage at the node netA is increased. At this time, the voltage at the node netA is set to reach a range higher than the threshold voltage of the TFT 100a. Note that the sensor output voltage Vom, which is supplied from the source of the TFT 100a during the readout pulse Prwn is being applied, is a voltage corresponding to a node netA voltage, that is, corresponding to a voltage which varies depending on light intensity. It is therefore possible to detect the light intensity by reading out, via the sensor output line Vom, the sensor output voltage Vom by use of the sensor readout circuit.

Note that, during the period (2), intensity of received light is high (bright) and the decrease in voltage at the node netA is large, whereas, during the period (6), intensity of received light is low (dark) and the decrease in voltage at the node netA is small.

Therefore, the sensor output voltage is low during the period (3), and the sensor output voltage is high during the period (7).

Patent Literature 2 discloses an optical sensor circuit as illustrated in FIG. 13.

In Patent Literature 2, a PhotoTFT is used which is configured, as a photodiode, by a so-called diode-connected TFT in which a gate and a drain are connected with each other (see FIG. 13). An output of the PhotoTFT is connected with a drain of a ReadoutTFT, which is a TFT for carrying out a readout. In a case where the ReadoutTFT is turned ON, a sensor output voltage is outputted from a source of the ReadoutTFT, and is read out by a charge readout amplifier.

### CITATION LIST

### Patent Literatures

### [Patent Literature 1]

International Publication No. WO2007/145347 A (Publication Date: Dec. 21, 2007)

### [Patent Literature 2]

U.S. Pat. No. 6,995,743 (Date of patent: Feb. 7, 2006)

### SUMMARY OF INVENTION

### Technical Problem

However, the optical sensor circuit disclosed in Patent Literature 1 has a problem that a sensor output S(signal)/N(noise) value and a D.R. (i.e., sensor output voltage obtained by low intensity of received light-sensor output voltage obtained by high intensity of received light) value are decreased.

This is caused because, although a sensor output voltage Vom obtained in response to received light having low intensity is higher than a sensor output voltage Vom obtained in response to received light having high intensity (see FIG. 12), in the case where the light has high intensity, a driving performance of the TFT 100a, which outputs a sensor output voltage, is increased by stray light caused by external light (i.e., mobility in TFT is improved by stray light), and the sensor output voltage Vom is heightened.

In a case where (i) the photodiode 100c is a photoelectric conversion element having a photoelectric conversion layer made of a-Si and (ii) light is used which has a wavelength (of 700 nm or longer) to which relative sensitivity of a-Si is low, there occurs a problem that a D.R. value is decreased.

The following description will discuss this phenomenon in detail, with reference to FIG. 14.

FIG. 14 is a graph illustrating a sensitivity characteristic, with respect to each wavelength, of the photodiode 100c having a light receiving layer made of a-Si. Relative sensitivity of a-Si, which is shown in a vertical axis of the graph is derived from a relation between a reverse bias electric current of the photodiode 100c and each wavelength. Specifically, the relative sensitivity indicates a reverse bias electric current which flows when the photodiode 100c is irradiated with isoenergic light of each wavelength. Note that a relative sensitivity, which is obtained when the photodiode 100c is irradiated with light having a wavelength of 540 nm, is considered as 1. That is, the relative sensitivity illustrated in FIG. 14 is calculated by Formula (1) below.

Relative sensitivity=I_{—}x nm/I_{—}540 nm (1)

In Formula (1), “I_x nm” indicates a reverse bias electric current which flows in response to light having a certain wavelength of x nm, and “I_{—}540 nm” indicates a reverse bias electric current which flows in response to light having a wavelength of 540 nm.

The relative sensitivity of a-Si becomes extremely low with respect to light having a wavelength of 700 nm or longer (see FIG. 14).

In a case where light intensity is to be detected with the use of light having a wavelength of 700 nm or longer, a D.R. value is decreased. This is because a capacitor 102b cannot sufficiently discharge during a certain period of time because a reverse bias electric current of the photodiode 100c does not flow sufficiently due to the low sensitivity, and therefore a voltage at the node netA, which is generated in response to received light with low intensity, becomes hardly different from a voltage at the node netA, which is generated in response to received light with high intensity.

As above described, the optical sensor circuit of Patent Literature 1 detects light intensity by utilizing an electric discharge caused by the reverse bias electric current of the photodiode 100c. This causes a problem that the sensing requires a certain amount of time for carrying out electric discharge, and therefore prompt sensing cannot be carried out.

In a case where light is used, which has a wavelength to which relative sensitivity of a-Si is high, there occurs a problem that a characteristic of the photodiode 100c is changed drastically and therefore nonuniformity of sensor output voltage Vom becomes large.

The following description will discuss this phenomenon with reference to FIG. 15.

FIG. 15 is a graph illustrating change in characteristic, which respect to each wavelength, of the photodiode 100c having a light receiving layer made of a-Si. (a) of FIG. 15 is a graph illustrating light absorption of an a-Si single film (having a thickness of 170 nm) with respect to each wavelength. (b) of FIG. 15 is a graph illustrating relative sensitivity of the photodiode 100c with respect to each wavelength. (c) of FIG. 15 is a graph illustrating relative characteristic change of the photodiode 100c with respect to each wavelength.

Here, “change in characteristic” indicates change in reverse bias electric current with respect to an original reverse bias electric current, which change is caused in a case where the photodiode 100c is irradiated with light having each wavelength for a predetermined continuous period of time. Specifically, a ratio of the change in characteristic (characteristic change ratio) is calculated in accordance with Formula (2) below.

Characteristic change ratio V (%)=(1−I2/I1)×100 (2)

In Formula (2), “I1” indicates an original reverse bias electric current and “I2” indicates a reverse bias electric current which flows after the photodiode 100c is irradiated with light having a certain wavelength for a predetermined period of time.

Note that (b) of FIG. 15 illustrates a case where relative sensitivity of 1 is obtained in response to light having a wavelength of 540 nm, and (c) of FIG. 15 illustrates a case where relative characteristic change of 1 is obtained in response to light having a wavelength of 365 nm. Specifically, the relative characteristic change illustrated in (c) of FIG. 15 can be calculated in accordance with Formula (3) below.

Relative characteristic change=V_{—}x nm/V_{—}365 nm (3)

In Formula (3), “V_x nm” indicates a characteristic change ratio obtained in response to light having a wavelength of x nm, and “V_{—}365 nm” indicates a characteristic change ratio obtained in response to light having a wavelength of 365 nm.

As the wavelength of light becomes longer, light absorption by the a-Si single film is decreased, and light having a wavelength of 750 nm or more is hardly absorbed (see FIG. 15). Moreover, as the wavelength of light becomes longer, the change in characteristic of the photodiode 100c, which is caused by the light absorption by the a-Si single film, tends to become smaller.

Under the circumstances, in a case where light intensity is to be detected with the use of light having a wavelength to which relative sensitivity of a-Si is high, (i) light absorption by the a-Si single film is increased, (ii) change in characteristic of the photodiode 100c over time becomes large, and (iii) nonuniformity of the sensor output voltage Vom becomes large.

According to the configuration of the optical sensor circuit disclosed in Patent Literature 2, the output of the PhotoTFT, which is a photodiode, is not connected with a gate of the ReadoutTFT. However, an output voltage from the photodiode is supplied as it is to an input of the charge readout amplifier, which serves as a load, via (i) the drain and the source of the ReadoutTFT and (ii) a line connected with the input of the charge readout amplifier. With the configuration, the output voltage from the photodiode is to be outputted without being subjected to power amplification by the ReadoutTFT. It is therefore necessary to increase capacitance of a capacitor Cst2 connected with the output of the PhotoTFT so that the ReadoutTFT remains turned ON after the capacitor Cst2 is charged with an output voltage supplied from the PhotoTFT for a long period of time. This requires an increase in element size of the capacitor Cst2. In a case where the capacitor Cst2 is enlarged, it is necessary to increase a reverse bias voltage to be applied to the PhotoTFT, which is the photodiode, so as to obtain large electric current capacity of the PhotoTFT. This leads to an increase in size of the PhotoTFT (photodiode), which increase in size is required for increasing a withstand voltage and decreasing a resistance. This causes a decrease in aperture ratio of a display device.

The optical sensor circuit of Patent Literature 2 also detects light intensity by utilizing an electric discharge caused by a reverse bias electric current of the PhotoTFT, which is the photodiode (phototransistor). There also occurs a problem that a prompt sensing cannot be carried out.

The present invention is accomplished in view of the conventional problems, and its object is to provide (i) an optical sensor circuit which suppresses a decrease in sensor accuracy and has high reliability and (ii) a display panel and a display device including the optical sensor circuit, which can suppress (a) a decrease in aperture ratio of pixel and (b) an increase in frame area around a display section.

### Solution to Problem

In order to attain the object, an optical sensor circuit of the present invention includes: a first transistor; and a second transistor, the first transistor being connected in series with the second transistor, the first transistor being configured to receive light, a light blocking member being provided so as to face the second transistor, and a voltage, which is generated at a connecting point of the first transistor and the second transistor, varying depending on intensity of light received via the first transistor.

Here, the light received via the first transistor encompasses lights of all wavelengths. That is, the light received via the first transistor encompasses at least ultraviolet light, visible light, and infrared light.

According to the configuration, it is possible to change the voltage generated at the connecting point immediately in accordance with a light receiving state of the first transistor. By sequentially reading out voltages at the connecting point, change in light receiving state can be promptly detected. That is, unlike the conventional configuration, the configuration of the present invention does not require a long-time electric discharge for carrying out sensing, and therefore detection accuracy can be maintained, even in a case where a high sensing frequency is employed.

Moreover, even in a case of detection of light having a wavelength to which a relative sensitivity is low, highly accurate detection can be carried out without a long-time electric discharge. That is, accuracy of an optical sensor can be improved, regardless of a wavelength of light to be detected.

Since a long-time electric discharge is not required for carrying out a sensing, a sensor output S/N value can be improved. This allows an improvement in reliability of an optical sensor.

A method for driving an optical sensor circuit of the present invention is a method for driving an optical sensor circuit including a first transistor, a second transistor, a third transistor, and a fourth transistor, the first transistor being connected in series with the second transistor, the first transistor being configured to receive light, a light blocking member being provided so as to face the second transistor, the fourth transistor having (i) a gate connected with a readout control line, (ii) a drain connected with a sensor output line, and (iii) a source connected with a drain of the third transistor, the third transistor having (i) a gate connected with a connecting point of the first transistor and the second transistor, (ii) the drain connected with the source of the fourth transistor, and (iii) a source connected with a power supply line, the second transistor having (i) a drain connected with a first voltage control line, (ii) a gate connected with a second voltage control line, and (iii) a source connected with a drain of the first transistor, the first transistor having (i) a gate connected with a third voltage control line, (ii) the drain connected with the source of the second transistor, and (iii) a source connected with a fourth voltage control line, and a voltage, which is generated at the connecting point, being controlled by use of the first through fourth voltage control lines, the method comprising the steps of: (a) applying voltages to the respective first through fourth voltage control lines; (b) applying a readout pulse to the readout control line connected with the gate of the fourth transistor during the step (a); and (c) causing a voltage, which has generated in response to light received by the first transistor, to be outputted via the third transistor, the fourth transistor, and the sensor output line, the voltage varying depending on intensity of the light received via the first transistor.

According to the configuration, it is possible to set a sensor output voltage, which is obtained in response to received light with high intensity, to be higher than a sensor output voltage obtained in response to received light with low intensity, by setting electric potentials of the first through fourth voltage control lines to respective predetermined values. It is therefore possible to prevent an S/N value (D.R. value) from being decreased due to stray light caused by external light. This allows an improvement in reliability of the optical sensor circuit.

According to the configuration, it is possible to change the voltage at the connecting point immediately in accordance with a light receiving state of the first transistor. By sequentially reading out voltages at the connecting point, change in light receiving state can be promptly detected.

That is, unlike the conventional configuration, the configuration of the present invention does not require a long-time electric discharge for carrying out sensing, and therefore detection accuracy can be maintained, even in a case where a high sensing frequency is employed.

Moreover, even in a case of detection of light having a wavelength to which a relative sensitivity is low, highly accurate detection can be carried out without a long-time electric discharge. That is, accuracy of an optical sensor can be improved, regardless of a wavelength of light to be detected.

Since a long-time electric discharge is not required for carrying out a sensing, a sensor output S/N value can be improved. This allows an improvement in reliability of an optical sensor.

### Advantageous Effects of Invention

The optical sensor circuit of the present invention includes a first transistor; and a second transistor, the first transistor being connected in series with the second transistor, a voltage, which is generated at a connecting point of the first transistor and the second transistor, varying depending on intensity of light received via the first transistor.

This brings about an effect of providing an optical sensor circuit which (i) suppresses a decrease in sensor accuracy and (ii) has high reliability.

### BRIEF DESCRIPTION OF DRAWINGS

FIG. 1 is an equivalent circuit diagram illustrating a display panel in accordance with Embodiment 1 of the present invention.

FIG. 2 is a block diagram illustrating a configuration of a main part of a liquid crystal display device, in accordance with Embodiment 1 of the present invention.

FIG. 3 is a cross-sectional view schematically illustrating a configuration of a main part of the liquid crystal display device, in accordance with Embodiment 1 of the present invention. (a) of FIG. 3 schematically illustrates a configuration of a main part of a liquid crystal display device in which a visible light blocking filter is not provided. (b) of FIG. 3 schematically illustrates a configuration of a main part of a liquid crystal display device in which a visible light blocking filter is provided.

FIG. 4 is a circuit diagram illustrating a configuration of a main part of the optical sensor circuit, in accordance with Embodiment 1 of the present invention.

FIG. 5 is an explanatory view for explaining an operation principle of an optical sensor circuit, in accordance with Embodiment 1 of the present invention.

FIG. 6 is a waveform chart for explaining the operation principle of the optical sensor circuit, in accordance with Embodiment 1 of the present invention.

FIG. 7 is an equivalent circuit diagram illustrating a display panel in accordance with Embodiment 2 of the present invention.

FIG. 8 is an equivalent circuit diagram illustrating a display panel in accordance with Embodiment 3 of the present invention.

FIG. 9 is an equivalent circuit diagram illustrating a display panel in accordance with Embodiment 4 of the present invention.

FIG. 10 is an equivalent circuit diagram illustrating a display panel in accordance with Embodiment 5 of the present invention.

FIG. 11 is an equivalent circuit diagram illustrating a display panel disclosed in Patent Literature 1.

FIG. 12 is a waveform chart for explaining how an optical sensor circuit disclosed in Patent Literature 1 operates.

FIG. 13 is an equivalent circuit diagram illustrating a display panel disclosed in Patent Literature 2.

FIG. 14 is a graph illustrating a sensitivity characteristic, with respect to each wavelength, of a photodiode 100c having a light receiving layer made of a-Si.

FIG. 15 is a graph illustrating change in characteristic, with respect to each wavelength, of the photodiode 100c having the light receiving layer made of a-Si.

### DESCRIPTION OF EMBODIMENTS

The following description will discuss embodiments of the present invention in detail.

### Embodiment 1

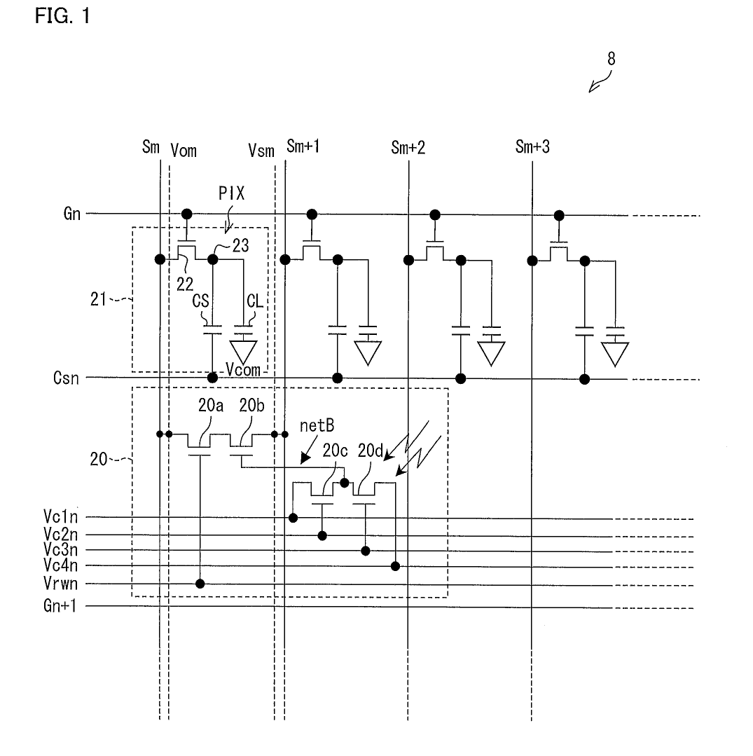

The following description will discuss Embodiment 1 of the present invention with reference to FIGS. 1 through 6. Specifically, the following description will discuss a case where an optical sensor circuit of the present embodiment is applied to a liquid crystal display device.

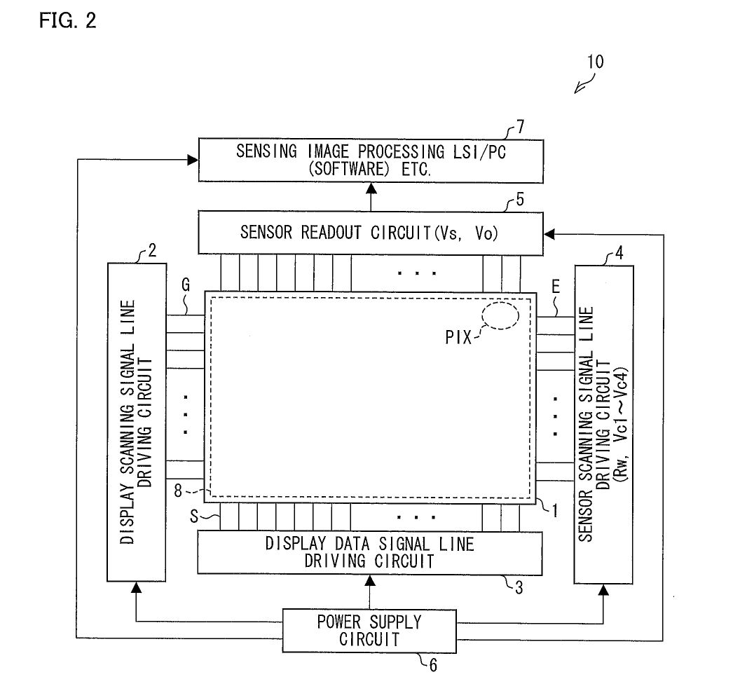

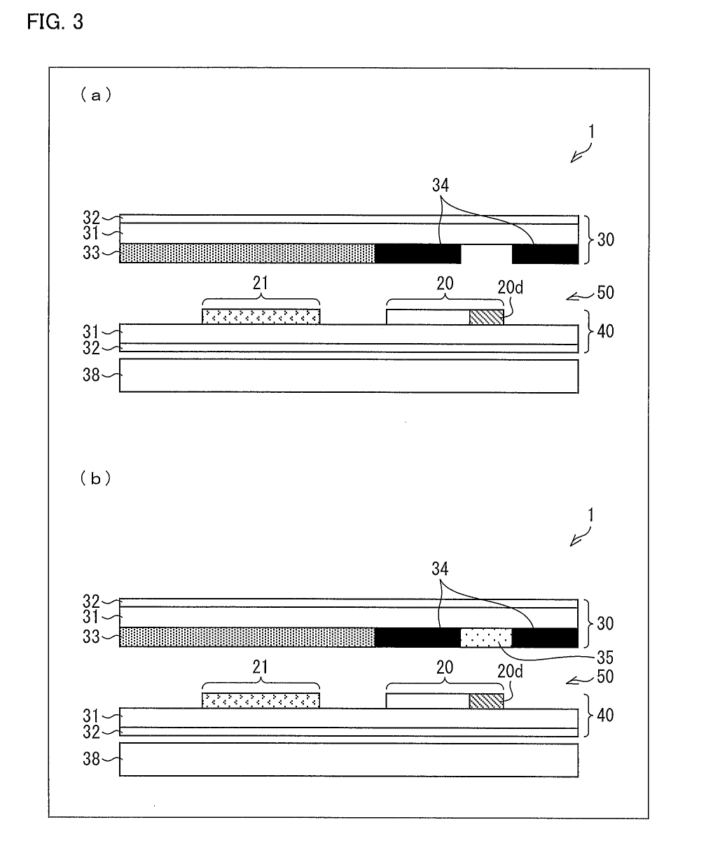

First, an entire configuration of a liquid crystal display device of Embodiment 1 will be described with reference to FIGS. 2 and 3.

FIG. 2 is a block diagram illustrating a configuration of a main part of the liquid crystal display device (display device), in accordance with Embodiment 1.

A liquid crystal display device 10 is an active matrix display device which includes a display panel 1, a display scanning signal line driving circuit 2, a display data signal line driving circuit 3, a sensor scanning signal line driving circuit 4, a sensor readout circuit 5, a power supply circuit 6, and a sensing image processing device 7.

The display panel 1 (i) includes a plurality of gate lines G and a plurality of source lines S which intersect with each other and (ii) has a display area 8 in which picture elements PIX, arranged in a matrix manner, are provided at respective intersections of the plurality of gate lines G and the plurality of source lines S.

The display scanning signal line driving circuit 2 drives the plurality of gate lines G by sequentially supplying, to the plurality of gate lines G, respective scanning signals for selecting picture elements PIX so that each data signal is written into a corresponding one of the picture elements PIX.

The display data signal line driving circuit 3 drives the plurality of source lines S by supplying data signals to the respective plurality of source lines S.

The sensor scanning signal line driving circuit 4 sequentially drives sensor scanning signal lines E by sequentially supplying, to the respective sensor scanning signal lines E, scanning signals (i.e., voltages Vc 1 through Vc4 and voltage Vrw) for operating an optical sensor circuit 20.

The sensor readout circuit 5 (i) reads out sensor output voltages Vo from respective sensor output lines Vo (for convenience, the same reference symbol is given to the sensor output voltage and the sensor output line) and (ii) supplies a power supply voltage to a power supply line Vs.

The power supply circuit 6 supplies voltages required for operating the display scanning signal line driving circuit 2, the display data signal line driving circuit 3, the sensor scanning signal line driving circuit 4, the sensor readout circuit 5, and the sensing image processing device 7.

The sensing image processing device 7 analyzes distribution of in-plane sensor detection results of the display panel 1 based on sensor output voltages Vo read out by the sensor readout circuit 5.

Note that the liquid crystal display device illustrated in FIG. 2 is merely an example, and therefore the display device is not limited to the configuration illustrated in FIG. 2. A function of the sensor scanning signal line driving circuit 4 and/or a function of the sensor readout circuit 5 can be therefore achieved by another circuit such as the display scanning signal line driving circuit 2 or the display data signal line driving circuit 3. Alternatively, the function of the sensor readout circuit 5 can be achieved by the sensing image processing device 7. Also note that the sensing image processing device 7 can be provided in the liquid crystal display device 10 in the form of, for example, an LSI chip or a computer. Alternatively, the sensing image processing device 7 can be provided outside of the liquid crystal display device 10. Similarly, the sensor readout circuit 5 can be provided outside of the liquid crystal display device 10.

FIG. 3 is a cross-sectional view schematically illustrating how a main part of the liquid crystal display device 10 is configured in Embodiment 1.

The display panel 1 has a configuration in which a liquid crystal layer 50 is provided between a counter substrate 30 and an active matrix substrate 40 (see (a) and (b) of FIG. 3).

The active matrix substrate 40 includes an insulating substrate 31 made of a material such as a glass plate. The insulating substrate 31 has (i) a surface on which a polarizing plate 32 is provided and (ii) an opposite surface on which the optical sensor circuit 20 and a display element driving circuit 21 are provided.

As with the active matrix substrate 40, the counter substrate 30 includes an insulating substrate 31 made of a material such as a glass plate. The insulating substrate 31 of the counter substrate 30 has (i) a surface on which members such as a color filter layer 33, a counter electrode (not illustrated), and an alignment film (not illustrated) are provided and (ii) an opposite surface on which the polarizing plate 32 is provided.

The color filter layer 33 has (i) three colored sections having respective colors of red (R), green (G), and blue (B) and (ii) a black matrix 34 (see (a) of FIG. 3). Note that the color filter layer 33 is provided so as not to face a transistor 20d provided in the optical sensor circuit 20.

According to the configuration, the black matrix 34 (light blocking member) is provided so as to face a transistor 20c (later described). This causes lights of all wavelengths to be blocked. On the other hand, the transistor 20d is provided so as to face an opening, and therefore the transistor 20d receives incoming light. The transistor 20d detects a received light amount, by passing an electric current which varies depending on intensity of received light.

A backlight 38 is provided behind the active matrix substrate 40, i.e., on a side of the active matrix substrate 40 on which side the polarizing plate 32 is provided. The backlight 38 includes a plurality of white LEDs as a light source.

In a state where light is emitted from the backlight 38, the optical sensor circuit 20 including the transistor 20d detects light reflected from, for example, a finger pulp of an operator who has touched the display panel 1. This is how the optical sensor circuit 20 detects where the operator has touched on the display panel 1.

However, although depending on circumstances in which the display panel 1 is used, intensity of visible light components contained in external light, which visible light components enter the TFT 20d, can become considerably high. In such a case, the following problem occurs. That is, the visible light components of the external light serves as a noise (N), and therefore sensitivity of the TFT 20d becomes decreased. This ultimately causes a deterioration in accuracy with which a touch sensor should sense.

In order to address the problem, a visible light blocking filter (infrared transmission filter) 35, which blocks visible light components, is preferably provided in a layer. The layer and the color filter layer 33 are juxtaposed to each other so as to constitute a single layer (see (b) of FIG. 3).

The visible light blocking filter 35 (i) is provided so as to face the TFT 20d provided on the active matrix substrate 40 and (ii) blocks light having wavelengths equal to or shorter than visible light wavelengths.

This provides a configuration in which visible light components of external light are difficult to enter the TFT 20d. As such, it is possible to carry out a stable sensing operation under various circumstances without being adversely affected by external circumstances (such as external light intensity) of the liquid crystal display device.

Here, the visible light blocking filter 35 preferably has an average transmittance of not more than 1% with respect to average visible light.

This allows external light to be prevented from entering the transistor 20d, which is provided under the visible light blocking filter 35.

Note that the visible light blocking filter 35, having an average visible light transmittance of not more than 1%, is preferably made up of a color filter having three layers of RGB.

With the configuration, the visible light blocking filter 35 can be concurrently formed with forming of the color filter layer 33. This allows a reduction in cost, as compared with a case where the visible light blocking filter 35 and the color filter layer 33 are made from respective different materials and in respective different processes.

The backlight 38 can employ, as a light source, a plurality of white LEDs and a plurality of infrared LEDs. Note that an infrared LED emits light having a wavelength falling within an infrared range. In a case where the plurality of infrared LEDs are employed in Embodiment 1, each of the plurality of infrared LEDs emits infrared light having wavelengths falling within the infrared range, in particular, infrared light which is transmitted by the visible light blocking filter (infrared light transmissive section) 35.

With the configuration, in a case where, for example, an operator touches the display panel 1, infrared light emitted from an infrared LED in the backlight 38 is reflected from a finger pulp of the operator, and the infrared light thus reflected can be detected by the optical sensor circuit 20. It is therefore possible to detect where the operator has touched on the display panel 1, in accordance with infrared light intensities detected by respective optical sensor circuits 20.

In a case where, for example, the TFT 20d has a light receiving layer made of a-Si (amorphous silicon), a characteristic of the TFT 20d hardly changes over time because infrared light is hardly absorbed by an a-Si film. This allows an improvement in reliability of the optical sensor circuit 20.

The following description will discuss, in detail, how the display area is configured with reference to FIG. 1.

According to the display area 8 of the display panel 1, a plurality of pixels arranged in a matrix manner. Each of the plurality of pixels is made up of three picture elements PIX of respective R, G, and B.

FIG. 1 is an equivalent circuit diagram illustrating a configuration of an extracted n-th row in the display area 8. According to the configuration of the n-th row, (i) a plurality of picture elements PIX are defined by a gate line Gn, source lines S (in FIG. 1, source lines Sm through Sm+3), and a retention capacitor line Csn and (ii) at least one optical sensor circuit 20 is provided which is connected with (a) node netB voltage control lines Vc1n through Vc4n and (b) a readout control line Vrwn, which lines Vc1n through Vc4n and Vrwn serve as the sensor scanning signal lines E. The retention capacitor line Csn, the node netB voltage control lines Vc1n through Vc4n, and the readout control line Vrwn are provided so as to extend in parallel with the gate line Gn.

Each of the plurality of picture elements PIX includes (i) a TFT 22 serving as a selection element and (ii) a display element driving circuit 21 made up of components such as a liquid crystal capacitor CL and a retention capacitor CS. The TFT 22 has (i) a gate connected with the gate line Gn, (ii) a source connected with the source line S, and (iii) a drain connected with the picture element electrode 23. The liquid crystal capacitor CL is a capacitor defined by the picture element electrode 23 and a common electrode Com between which a liquid crystal layer is provided. The retention capacitor CS is a capacitor defined by (i) the picture element electrode 23 or the drain electrode of the TFT 22 and (ii) the retention capacitor line Csn, between which an insulating film is provided. For example, constant voltages are applied to respective of the common electrode Com and the retention capacitor line Csn.

The number of the optical sensor circuit(s) 20 is set arbitrarily. That is, an optical sensor circuit 20 can be provided, for example, (i) per pixel made up of a single picture element PIX or a plurality of picture elements PIX (for example, one (1) pixel is made up of a set of three picture elements PIX of respective R, G, and B), (ii) per plural picture elements PIX, or (iii) per plural pixels. The optical sensor circuit 20 includes a TFT (sensor output transistor) 20a, a TFT (sensor output voltage control transistor) 20b, a TFT (node netB voltage dividing transistor) 20c, and a TFT (phototransistor) 20d.

The TFT 20a (fourth transistor) has (i) a gate connected with the readout control line Vrwn, (ii) a drain connected with the source line S (here, the source line Sm), and (iii) a source connected with a drain of the TFT 20b.

The TFT 20b (third transistor) has (i) a gate connected with an electrode referred to as “node netB”, (ii) a drain connected with a source of the TFT 20a, and (iii) a source connected with the source line S (here, the source line Sm+1).

The TFT 20c (second transistor) has (i) a gate connected with the node netB voltage control line Vc2n (second voltage control line), (ii) a drain connected with the node netB voltage control line Vc1n (first voltage control line), and (iii) a source connected with a drain of the TFT 20d.

The TFT 20d (first transistor) has (i) a gate connected with the node netB voltage control line Vc3n (third voltage control line), (ii) a drain connected with the source of the TFT 20c, and (iii) a source connected with the node netB voltage control line Vc4n (fourth voltage control line).

One end of the node netB is connected with the gate of the TFT 20b, and the other end of the node netB is connected with a connecting point of the source of the TFT 20c and the drain of the TFT 20d.

The optical sensor circuit 20 is configured so as to (i) output, as a sensor output voltage Vom from the drain of the TFT 20a during a period other than a period in which a data signal is written into a picture element PIX, an output voltage which is generated at the node netB in accordance with the intensity of light received via the TFT 20d and (ii) supply, via the source line S (which serves as a sensor output line Vom during a light detection) connected with the drain of the TFT 20a, the output voltage to the sensor readout circuit 5 provided outside of the display area. At this time (i.e., during the light detection), the source line S connected with the source of the TFT 20b serves as a power supply line Vsm to which a constant voltage is applied. Thus, the source line S serves also as the sensor output line Vom and the source line S serves also as the power supply line Vsm. Note, however, that Embodiment 1 is not limited to such a configuration. Therefore, the sensor output line Vom and the power supply line Vsm can be provided as lines which are separated from the respective source lines S, as indicated in FIG. 1 by dotted lines in the vicinity of the respective source lines S.

Note that (i) the TFT 22 which serves as a selection element for the picture element PIX and (ii) the TFTs 20a through 20d included in the optical sensor circuit 20, are preferably formed on the active matrix substrate 40 by substantially identical processes.

This allows (i) a reduction in production cost and (ii) a suppression of increase in the number of processes.

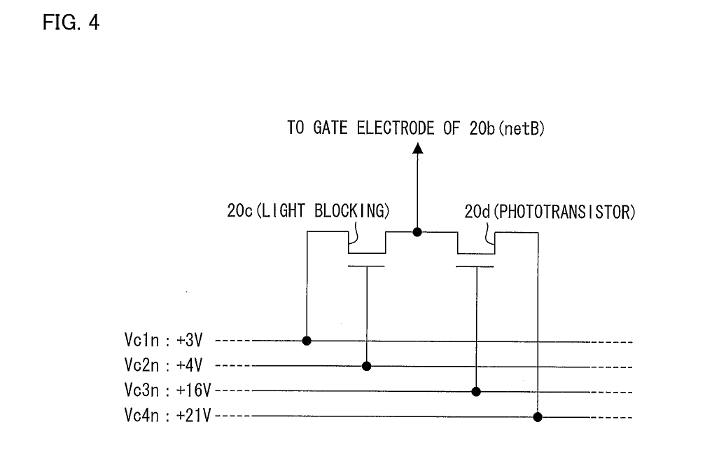

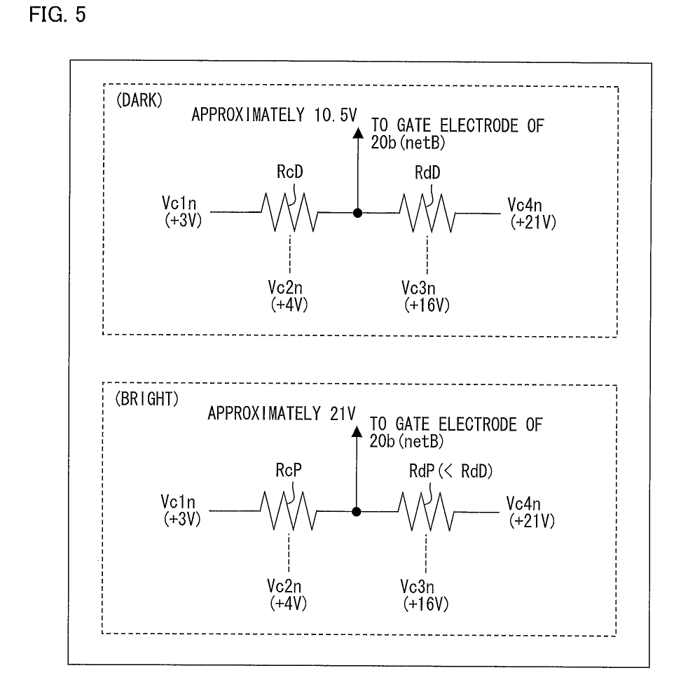

The following description will discuss, with reference to FIGS. 4 and 5, a principle of how a voltage, which is generated at the node netB, changes in accordance with intensity of light received via the TFT 20d.

FIG. 4 is a view illustrating a configuration of a main part of the optical sensor circuit 20.

The TFT 20c has (i) the gate connected with the node netB voltage control line Vc2n, (ii) the drain connected with the node netB voltage control line Vc1n, and (iii) the source connected with the drain of the TFT 20d (see (a) of FIG. 4).

The TFT 20d has (i) the gate connected with the node netB voltage control line Vc3n, (ii) the drain connected with the source of the TFT 20c, and (iii) the source connected with the node netB voltage control line Vc4n.

Note that the gate (node netB) of the TFT 20b is connected with a connecting point of the TFT 20c and the TFT 20d.

A constant voltage of, for example, +3 V is applied to the node netB voltage control line Vc1n. A constant voltage of, for example, +4 V is applied to the node netB voltage control line Vc2n. A constant voltage of, for example, +16 V is applied to the node netB voltage control line Vc3n. A constant voltage of, for example, +21 V is applied to the node netB voltage control line Vc4n.

FIG. 5 is a circuit diagram illustrating a case where the TFT 20c and the TFT 20d are considered as respective resistors.

In FIG. 5, “RcD” indicates a resistance of the TFT 20c which corresponds to a case where intensity of light emitted toward the TFT 20c is low (dark), and “RcP” indicates a resistance of the TFT 20c which corresponds to a case where intensity of light emitted toward the TFT 20c is high (bright). Further, in FIG. 5, “RdD” indicates a resistance of the TFT 20d which corresponds to a case where intensity of light emitted toward the TFT 20d is low (dark), and “RdP” indicates a resistance of the TFT 20d which corresponds to a case where intensity of light emitted toward the TFT 20d is high (bright).

The TFT 20c is not affected by intensity of emitted light, because the TFT 20c is subjected to light shielding. Therefore, the resistance of the resistor RcD is substantially identical with that of the resistance RcP.

On the other hand, while the TFT 20d is receiving the light, the resistance of TFT 20d changes so as to meet RdD>RdP. This is because, (i) while the TFT 20d is receiving light, electrons and positive holes are generated. This causes the TFT 20d to be in a low resistance state, whereas, (ii) while the TFT 20d is being subjected to light shielding, neither electron and nor positive hole are generated by light. This causes the TFT 20d to be in a high resistance state.

Under the circumstances, a voltage, which is generated at the node netB in a case where the intensity of received light is high (bright), becomes higher than a voltage which is generated at the node netB in a case where the intensity of received light is low (dark). This causes an improvement in electric current supplying capacity of the TFT 20b while the intensity of received light is being high (bright). This ultimately causes a sensor output voltage Vom to become higher.

Note that a midpoint electric potential of the voltage applied to the Vc1n (+3 V) and the voltage applied to the Vc4n (+21 V) (i.e., a voltage at the connecting point of the drain of the TFT 20d and the source of the TFT 20c) is outputted as a voltage of the node netB (hereinafter, referred to as “node netB voltage”). In a case where, for example, the TFT 20c and the TFT 20d have substantially identical sizes, (i) a node netB voltage of approximately 10.5 V is outputted when the TFT 20d has received light with low intensity (dark) (see an upper part of FIG. 5), and (ii) a node netB voltage of approximately 21 V is outputted when the TFT 20d has received light with high intensity (bright) (see a lower part of FIG. 5).

According to a conventional circuit configuration, a certain node has been discharged by a reverse bias electric current of a photodiode so that intensity of irradiated light is detected. This causes a sensor output difference to be generated. Time necessary for sensing, which time is assigned to each of optical sensor circuits, is a sum of discharge time and readout time. In a case where a sensing frequency is high, discharge time becomes short. Under the circumstances, it has been necessary to take measures, in order to prevent a decrease in S/N value (D.R. value), such as enlarging a size of the photodiode and/or improving sensitivity to each wavelength.

On the other hand, according to Embodiment 1, since a node netB voltage is changed immediately in accordance with intensity of light received via the TFT 20d, the discharge time is not required unlike the conventional circuit configuration. Embodiment 1 is therefore particularly advantageous to a case where a sensing frequency is high.

Moreover, according to Embodiment 1, the node netB voltage control lines Vc1n through Vc4n are set to have respective predetermined electric potential (in particular, an electric potential of the node netB voltage control line Vcln is set to be lower than that of the node netB voltage control line Vc4n). This allows a sensor output voltage Vom, which is obtained when intensity of received light is high, to be higher than that obtained when intensity of received light is low. It is therefore possible to prevent an S/N value (D.R. value) from being decreased by an influence of stray light caused by external light. This allows an improvement in reliability of an optical sensor circuit.

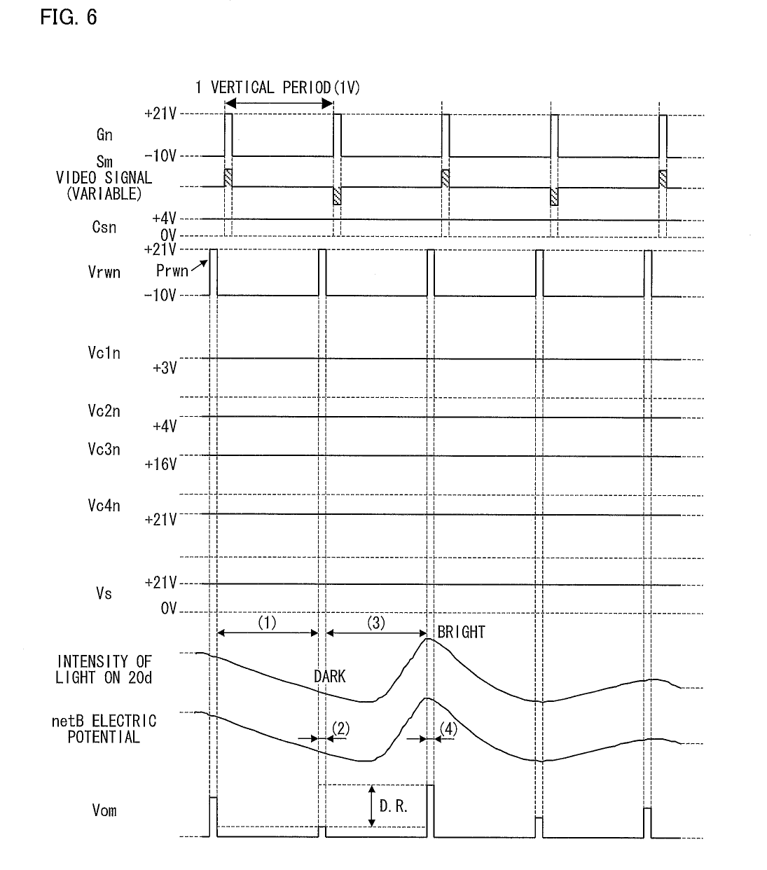

The following description will discuss, with reference to FIG. 6, details of how the optical sensor circuit 20 operates.

During a period in which data signals are written, (i) a gate pulse, which has a High level (e.g., +21 V) and a Low level (e.g., −10 V), is supplied as a scanning signal to the gate line Gn and (ii) data signals are supplied to the respective source lines S. A constant voltage of, for example, +4 V is applied to the retention capacitor line Csn. These operations are carried out with respect to picture elements PIX in each row for every vertical period (1V). During a period other than the period in which the data signals are written, results of light detection carried out by the optical sensor circuit 20 can be supplied to the sensor readout circuit 5. Note that results of light detection carried out by the optical sensor circuit 20 can be supplied to the sensor readout circuit 5, regardless of whether or not data signals are in the process of being written, in the case where the sensor output line Vom and the power supply line Vsm are provided as lines separated from the source lines S, respectively (see dotted lines in the vicinity of the respective source lines S illustrated in FIG. 1).

A constant voltage of, for example, +3 V is applied to the node netB voltage control line Vc1n. A constant voltage of, for example, +4 V is applied to the node netB voltage control line Vc2n. A constant voltage of, for example, +16 V is applied to the node netB voltage control line Vc3n. A constant voltage of, for example, +21 V is applied to the node netB voltage control line Vc4n.

During a period (1) illustrated in FIG. 6, intensity of light received via the TFT 20d is gradually decreased (i.e., becomes darker), and a node netB voltage is decreased in proportion to the decrease in intensity of received light.

During a period (2) illustrated in FIG. 6, in a case where a readout pulse Prwn, having a High level (e.g., +21 V) and a Low level (e.g., −10 V), is supplied from the sensor readout circuit 5 to the readout control line Vrwn, the TFT 20a starts a readout operation, and the TFT 20a supplies, as a sensor output voltage Vom, a voltage which varies depending on a node netB voltage from the drain of the TFT 20a to the sensor readout circuit 5, which is provided outside of the display area, via the source line S (which serves as a sensor output line Vom during light detection) connected with the drain of the TFT 20a. Note that the sensor output voltage Vom is a voltage which varies depending on a node netB voltage, that is, a voltage which varies depending on a voltage which has been generated at the connecting point in accordance with light intensity. It is therefore possible to detect the light intensity, by reading out, via the sensor output line Vom, the sensor output voltage Vom by use of the sensor readout circuit 5.

During a period (3) illustrated in FIG. 6, the application of the readout pulse Prwn to the readout control line Vrwn is stopped, and therefore the readout operation carried out by the TFT 20a is stopped. During the period (3), intensity of light received via the TFT 20d is gradually increased (i.e., becomes brighter), and a node netB voltage is increased in proportion to the increase in intensity of received light.

During a period (4) illustrated in FIG. 6, in a case where a readout pulse Prwn, having a High level (e.g., +21 V) and a Low level (e.g., −10 V), is supplied from the sensor readout circuit 5 to the readout control line Vrwn again, the TFT 20a starts a readout operation, and the TFT 20a supplies, as a sensor output voltage Vom, a voltage which varies depending on a node netB voltage (i.e., a voltage which varies depending on intensity of received light) from the drain of the TFT 20a to the sensor readout circuit 5, which is provided outside of the display area, via the source line S (which serves as a sensor output line Vom during light detection) connected with the drain of the TFT 20a. Note that, when the application of the readout pulse Prwn to the readout control line Vrwn is stopped, the readout operation carried out by the TFT 20a is stopped accordingly.

Note that, since the intensity of light received via the TFT 20d during the period (2) is different from that of light received via the TFT 20d during the period (4), the sensor output voltages Vom are different between the periods (2) and (4). Specifically, the intensity of light received via the TFT 20d during the period (4) is higher (brighter) and therefore the node netB voltage becomes higher. This causes an improvement in electric current supplying capacity of the TFT 20b. Therefore, a sensor output voltage Vom becomes higher.

The sensor readout circuit 5 reads out sensor output voltages Vom from the respective source lines S (which serve as the respective sensor output lines Vom during light detection). The sensing image processing device 7 analyzes distribution of in-plane sensor detection results of the display panel 1 based on sensor output voltages Vom read out by the sensor readout circuit 5.

### Embodiment 2

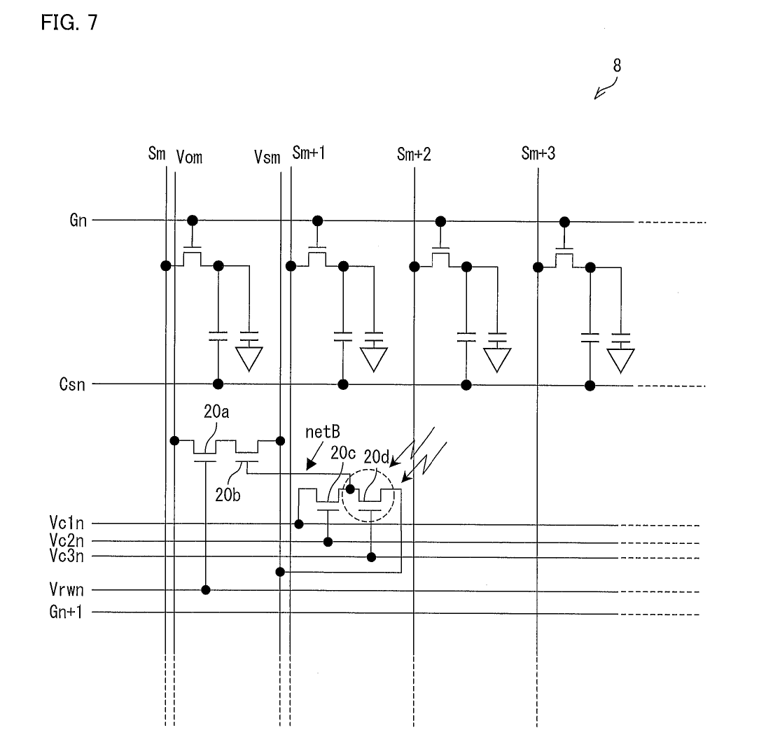

The following description will discuss, with reference to FIG. 7, a liquid crystal display device in accordance with Embodiment 2.

For convenience, the same reference numerals are given to constituents which have functions identical with those described in Embodiment 1 with reference to the drawings, and descriptions regarding such constituents are omitted.

FIG. 7 is a view illustrating a configuration of an extracted n-th row in a display area of a liquid crystal display panel of Embodiment 2.

The number of an optical sensor circuit(s) 20 is set arbitrarily. That is, an optical sensor circuit 20 can be provided, for example, (i) for each picture element PIX or (ii) for each pixel which is made up of a set of three picture elements PIX of respective R, G, and B. The optical sensor circuit 20 includes a TFT 20a, a TFT 20b, a TFT 20c, and a TFT 20d (see FIG. 7).

The TFT 20a has (i) a gate connected with a readout control line Vrwn, (ii) a drain connected with a sensor output line Vom, and (iii) a source connected with a drain of the TFT 20b.

The TFT 20b has (i) a gate connected with an electrode referred to as “node netB”, (ii) the drain connected with the source of the TFT 20a, and (iii) a source connected with a power supply line Vsm.

The TFT 20c has (i) a gate connected with a node netB voltage control line Vc2n, (ii) a drain connected with a node netB voltage control line Vc1n, and (iii) a source connected with a drain of the TFT 20d.

The TFT 20d has (i) a gate connected with a node netB voltage control line Vc3n, (ii) the drain connected with the source of the TFT 20c, and (iii) a source connected with the power supply line Vsm.

As above described, the source of the TFT 20d of Embodiment 2 is connected with the power supply line Vsm instead of a node netB voltage control line Vc4n. That is, Embodiment 2 is different from Embodiment 1 in that no node netB voltage control line Vc4n is provided in Embodiment 2.

During a period in which data signals are written, (i) a gate pulse having a High level (e.g., +21 V) and a Low level (e.g., −10 V) is supplied as a scanning signal to the gate line Gn and (ii) data signals are supplied to the respective source lines S. A constant voltage of, for example, +4 V is applied to the retention capacitor line Csn. Note that, in Embodiment 2, the sensor output line Vom and the power supply line Vsm are provided as lines separated from the respective source lines S. With the configuration, results of light detection, carried out by the optical sensor circuit 20 can be supplied to the sensor readout circuit 5, regardless of whether or not data signals are in the process of being written. A constant voltage of, for example, +21 V is applied to the power supply line Vsm.

A constant voltage of, for example, +5 V is applied to the node netB voltage control line Vc1n. A constant voltage of, for example, +7 V is applied to the node netB voltage control line Vc2n. A constant voltage of, for example, +10 V is applied to the node netB voltage control line Vc3n.

In Embodiment 2, the power supply line Vsm serves also as a node netB voltage control line Vc4n. This allows a reduction in number of (i) power sources whose voltages are supplied from a power supply circuit 6 and (ii) wirings. It is therefore possible to prevent a decrease in aperture ratio of a display device which includes the optical sensor circuit 20.

Note that Embodiment 2 is not limited to the configuration in which the sensor output line Vom and the power supply line Vsm are provided as lines separated from the respective source lines S. Embodiment 2 can therefore employ a configuration in which (i) a source line S serves also as the sensor output line Vom and (ii) a source line S serves also as the power supply line Vsm, as with Embodiment 1.

### Embodiment 3

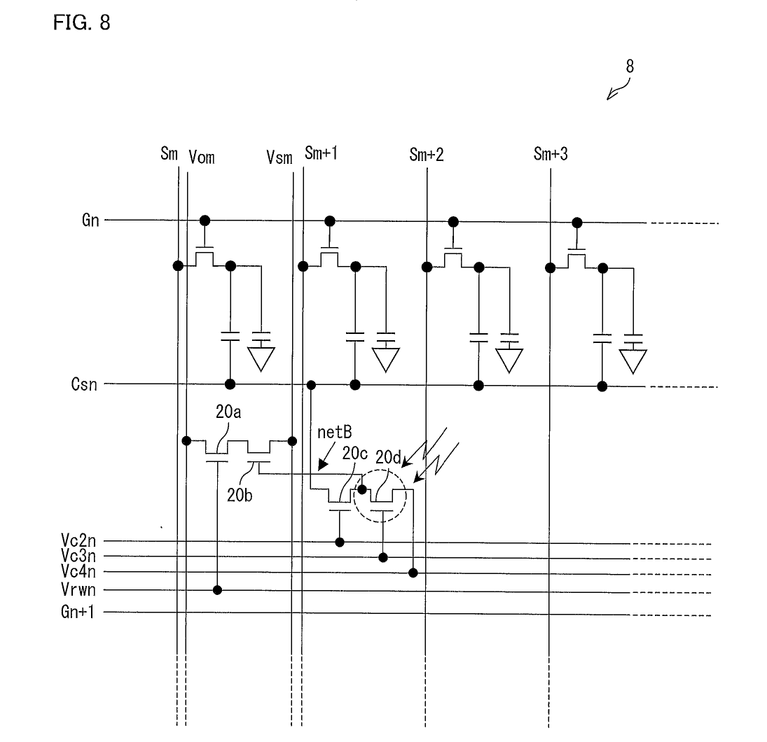

The following description will discuss, with reference to FIG. 8, a liquid crystal display device in accordance with Embodiment 3.

For convenience, the same reference numerals are given to constituents which have functions identical with those described in Embodiment 1 with reference to the drawings, and descriptions regarding such constituents are omitted.

FIG. 8 is a view illustrating a configuration of an extracted n-th row in a display area of a liquid crystal display panel of Embodiment 3.

The number of an optical sensor circuit(s) 20 is set arbitrarily. That is, an optical sensor circuit 20 can be provided, for example, (i) for each picture element PIX or (ii) for each pixel which is made up of a set of three picture elements PIX of respective R, G, and B. The optical sensor circuit 20 includes a TFT 20a, a TFT 20b, a TFT 20c, and a TFT 20d (see FIG. 8).

The TFT 20a has (i) a gate connected with a readout control line Vrwn, (ii) a drain connected with a sensor output line Vom, and (iii) a source connected with a drain of the TFT 20b.

The TFT 20b has (i) a gate connected with an electrode referred to as “node netB”, (ii) the drain connected with the source of the TFT 20a, and (iii) a source connected with a power supply line Vsm.

The TFT 20c has (i) a gate connected with a node netB voltage control line Vc2n, (ii) a drain connected with a retention capacitor line Csn, and (iii) a source connected with a drain of the TFT 20d. The drain of the TFT 20c of Embodiment 3 is thus not connected with a node netB voltage control line Vc1n but is connected with the retention capacitor line Csn which is provided in the display panel 1 so as to retain a liquid crystal capacitor. That is, Embodiment 3 is different from Embodiment 1 in that no node netB voltage control line Vcln is provided in Embodiment 3.

The TFT 20d has (i) a gate connected with a node netB voltage control line Vc3n, (ii) the drain connected with the source of the TFT 20c, and (iii) a source connected with a node netB voltage control line Vc4n.

During a period in which data signals are written, (i) a gate pulse, having a High level (e.g., +21 V) and a Low level (e.g., −10 V), is supplied as a scanning signal to the gate line Gn and (ii) data signals are supplied to the respective source lines S. A constant voltage of, for example, +3 V is applied to the retention capacitor line Csn. Note that, in Embodiment 3, the sensor output line Vom and the power supply line Vsm are provided as lines separated from the respective source lines S. With the configuration, results of light detection, which has been carried out by the optical sensor circuit 20, can be supplied to the sensor readout circuit 5, regardless of whether or not data signals are in the process of being written. A constant voltage of, for example, +21 V is applied to the power supply line Vsm.

A constant voltage of, for example, +7 V is applied to the node netB voltage control line Vc2n. A constant voltage of, for example, +10 V is applied to the node netB voltage control line Vc3n. A constant voltage of, for example, +21 V is applied to the node netB voltage control line Vc4n.

In Embodiment 3, the retention capacitor line Csn serves also as a node netB voltage control line Vc1n. This allows a reduction in number of (i) power sources whose voltages are supplied from a power supply circuit 6 and (ii) wirings. It is therefore possible to prevent a decrease in aperture ratio of a display device which includes the optical sensor circuit 20.

Note that Embodiment 3 is not limited to the configuration in which the sensor output line Vom and the power supply line Vsm are provided as lines separated from the respective source lines S. Embodiment 3 can therefore employ a configuration in which (i) a source line S serves also as the sensor output line Vom and (ii) a source line S serves also as the power supply line Vsm, as with Embodiment 1.

### Embodiment 4

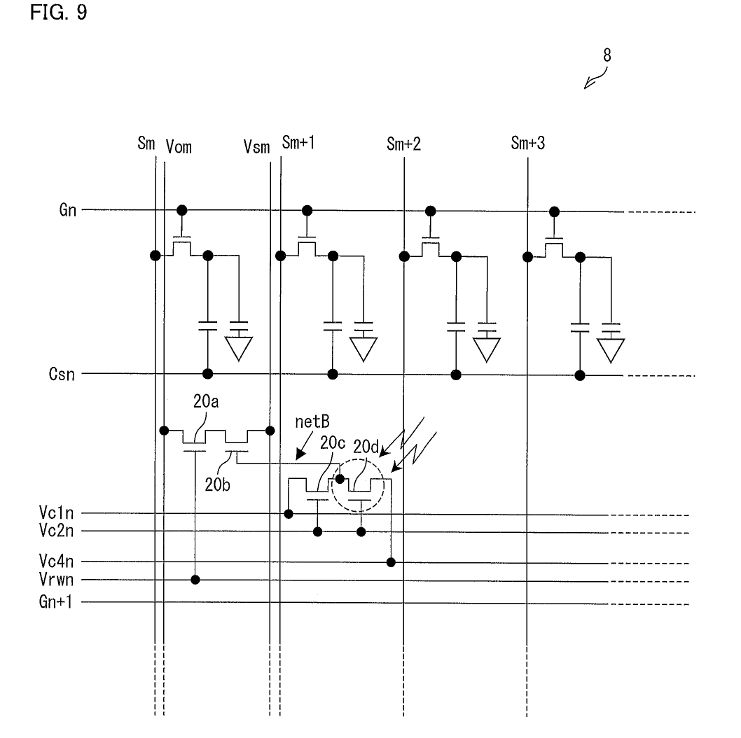

The following description will discuss, with reference to FIG. 9, a liquid crystal display device in accordance with Embodiment 4.

For convenience, the same reference numerals are given to constituents which have functions identical with those described in Embodiment 1 with reference to the drawings, and descriptions regarding such constituents are omitted.

FIG. 9 is a view illustrating a configuration of an extracted n-th row in a display area of a liquid crystal display panel of Embodiment 4.

The number of an optical sensor circuit(s) 20 is set arbitrarily. That is, an optical sensor circuit 20 can be provided, for example, (i) for each picture element PIX or (ii) for each pixel which is made up of a set of three picture elements PIX of respective R, G, and B. The optical sensor circuit 20 includes a TFT 20a, a TFT 20b, a TFT 20c, and a TFT 20d (see FIG. 9).

The TFT 20a has (i) a gate connected with a readout control line Vrwn, (ii) a drain connected with a sensor output line Vom, and (iii) a source connected with a drain of the TFT 20b.

The TFT 20b has (i) a gate connected with an electrode referred to as “node netB”, (ii) the drain connected with the source of the TFT 20a, and (iii) a source connected with a power supply line Vsm.

The TFT 20c has (i) a drain connected with a node netB voltage control line Vc1n, (ii) a gate connected with a node netB voltage control line Vc2n, and (iii) a source connected with a drain of the TFT 20d.

The TFT 20d has (i) a gate connected with a node netB voltage control line Vc2n, (ii) the drain connected with the source of the TFT 20c, and (iii) a source connected with a node netB voltage control line Vc4n. As such, the gate of the TFT 20d of Embodiment 4 is connected with the node netB voltage control line Vc2n instead of a node netB voltage control line Vc3n. That is, Embodiment 4 is different from Embodiment 1 in that no node netB voltage control line Vc3n is provided in Embodiment 4.

During a period in which data signals are written, (i) a gate pulse having a High level (e.g., +21 V) and a Low level (e.g., −10 V) is supplied as a scanning signal to the gate line Gn and (ii) data signals are supplied to the respective source lines S. A constant voltage of, for example, +4 V is applied to the retention capacitor line Csn. Note that, in Embodiment 4, the sensor output line Vom and the power supply line Vsm are provided as lines separated from the respective source lines S. With the configuration, results of light detection, which has been carried out by the optical sensor circuit 20, can be supplied to the sensor readout circuit 5, regardless of whether or not data signals are in the process of being written. A constant voltage of, for example, +21 V is applied to the power supply line Vsm.

A constant voltage of, for example, +5 V is applied to the node netB voltage control line Vc1n. A constant voltage of, for example, +10 V is applied to the node netB voltage control line Vc2n. A constant voltage of, for example, +21 V is applied to the node netB voltage control line Vc4n.

In Embodiment 4, the node netB voltage control line Vc2n serves also as a node netB voltage control line Vc3n. This allows a reduction in number of (i) power sources whose voltages are supplied from a power supply circuit 6 and (ii) wirings. It is therefore possible to prevent a decrease in aperture ratio of a display device which includes the optical sensor circuit 20.

Note that Embodiment 4 is not limited to the configuration in which the sensor output line Vom and the power supply line Vsm are provided as lines separated from the respective source lines S. Embodiment 4 can therefore employ a configuration in which (i) a source line S serves also as the sensor output line Vom and (ii) a source line S serves also as the power supply line Vsm, as with Embodiment 1.

### Embodiment 5

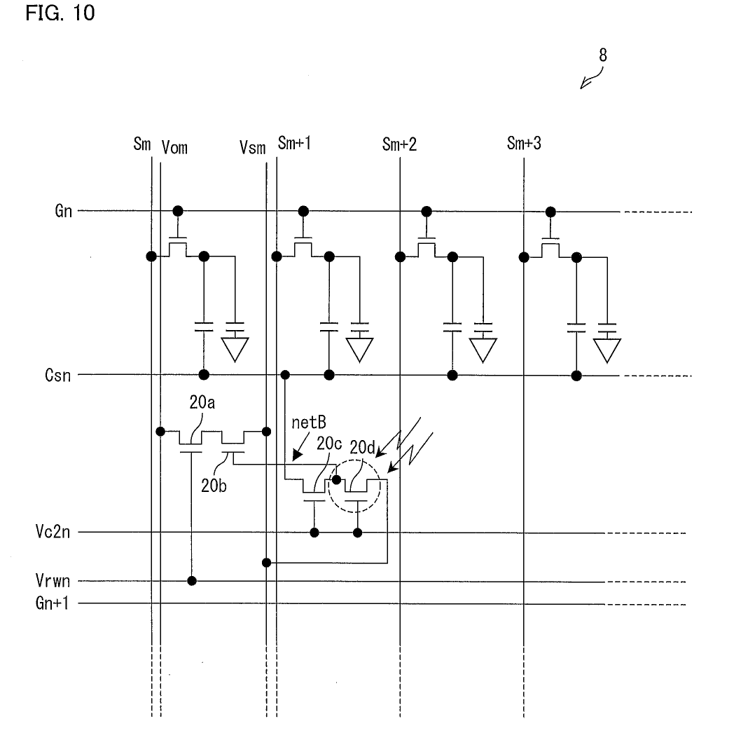

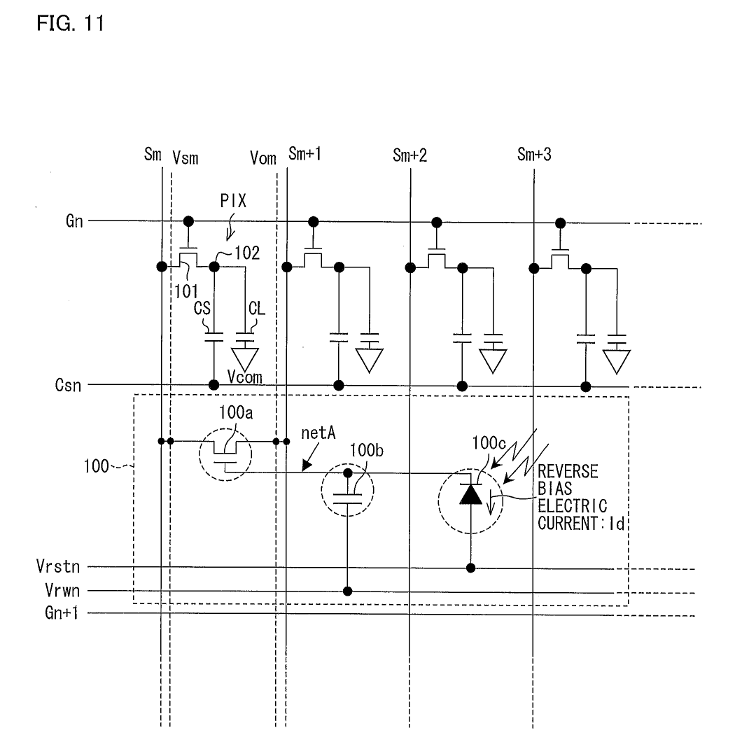

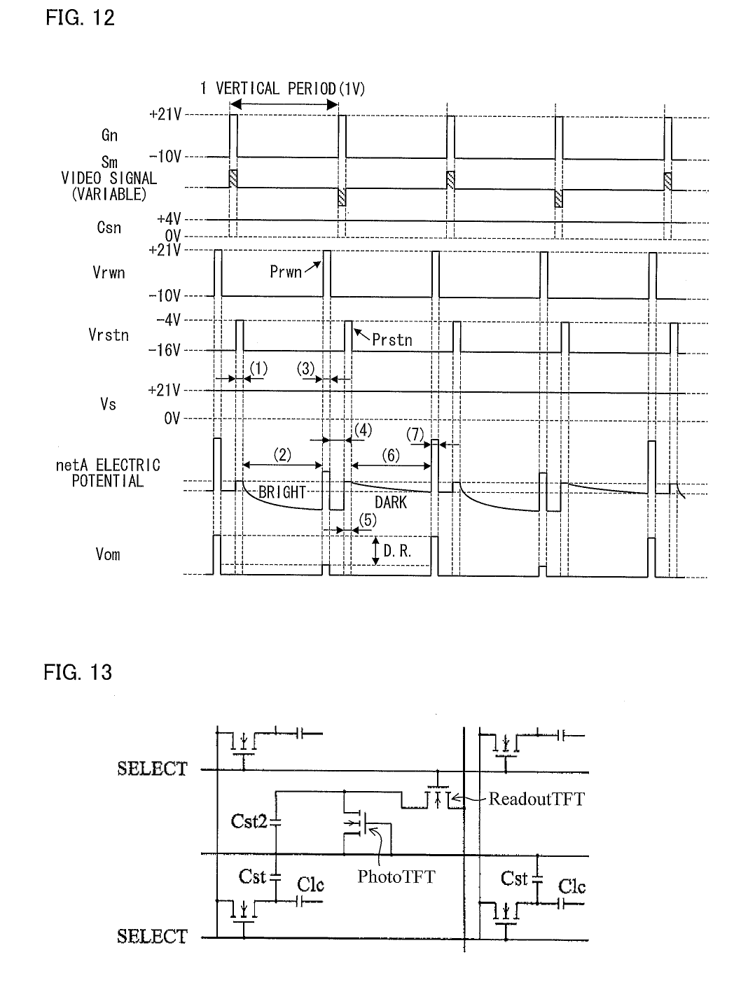

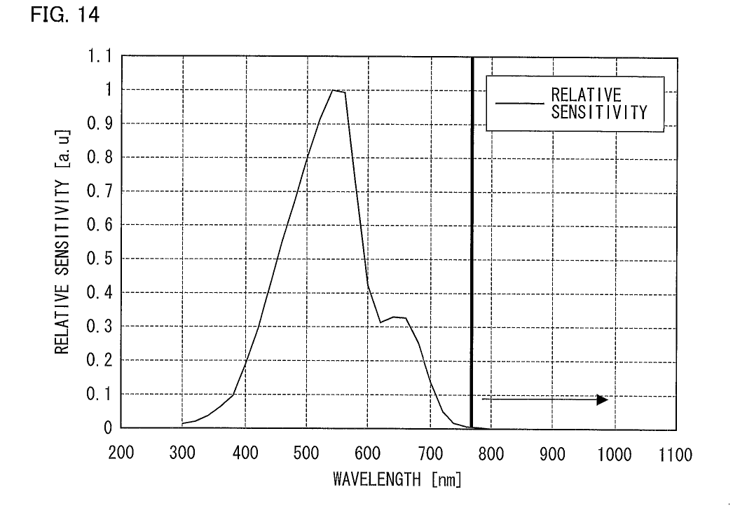

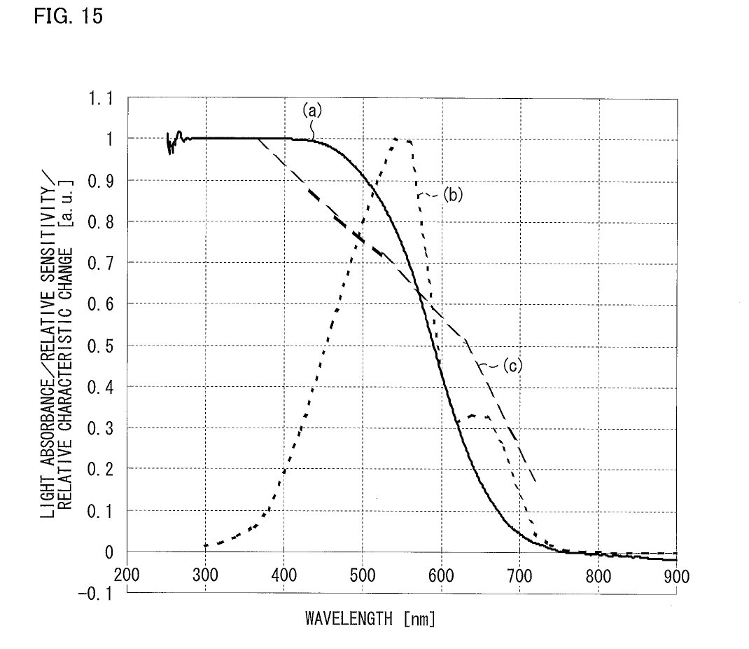

The following description will discuss, with reference to FIG. 10, a liquid crystal display device in accordance with Embodiment 5.

For convenience, the same reference numerals are given to constituents which have functions identical with those described in Embodiment 1 with reference to the drawings, and descriptions regarding such constituents are omitted.

FIG. 10 is a view illustrating a configuration of an extracted n-th row in a display area of a liquid crystal display panel of Embodiment 5.

The number of an optical sensor circuit(s) 20 is set arbitrarily. That is, an optical sensor circuit 20 can be provided, for example, (i) for each picture element PIX or (ii) for each pixel which is made up of a set of three picture elements PIX of respective R, G, and B. The optical sensor circuit 20 includes a TFT 20a, a TFT 20b, a TFT 20c, and a TFT 20d (see FIG. 10).

The TFT 20a has (i) a gate connected with a readout control line Vrwn, (ii) a drain connected with a sensor output line Vom, and (iii) a source connected with a drain of the TFT 20b.

The TFT 20b has (i) a gate connected with an electrode referred to as “node netB”, (ii) the drain connected with the source of the TFT 20a, and (iii) a source connected with a power supply line Vsm.

The TFT 20c has (i) a gate connected with a node netB voltage control line Vc2n, (ii) a drain connected with a retention capacitor line Csn, and (iii) a source connected with a drain of the TFT 20d.

The TFT 20d has (i) a gate connected with a node netB voltage control line Vc2n, (ii) the drain connected with the source of the TFT 20c, and (iii) a source connected with the power supply line Vsm.

A constant voltage of, for example, +10 V is applied to the node netB voltage control line Vc2n. A constant voltage of, for example, +21 V is applied to the power supply line Vsm. A constant voltage of, for example, +3 V is applied to the retention capacitor line Csn.

During a period in which data signals are written, (i) a gate pulse having a High level (e.g., +21 V) and a Low level (e.g., −10 V) is supplied as a scanning signal to the gate line Gn and (ii) data signals are supplied to the respective source lines S. A constant voltage of, for example, +3 V is applied to the retention capacitor line Csn. Note that, in Embodiment 5, the sensor output line Vom and the power supply line Vsm are provided as lines separated from the source lines S. With the configuration, results of light detection, which has been carried out by the optical sensor circuit 20, can be supplied to the sensor readout circuit 5, regardless of whether or not data signals are in the process of being written. A constant voltage of, for example, +21 V is applied to the power supply line Vsm.

A constant voltage of, for example, +10 V is applied to the node netB voltage control line Vc2n.

In Embodiment 5, (i) the power supply line Vsm serves also as a node netB voltage control line Vc4n, (ii) the retention capacitor line Csn serves also as a node netB voltage control line Vc1n, and (iii) the node netB voltage control line Vc2n serves also as a node netB voltage control line Vc3n.

Embodiment 5 is different from Embodiment 1 in that each of the node netB voltage control line Vc1n, the node netB voltage control line Vc3n, and the node netB voltage control line Vc4n is realized by a corresponding one of other lines, that is, each of the lines Vc1n, Vc3n, and Vc4n is not provided as an independent constituent in Embodiment 5. This allows a reduction in number of (i) power sources whose voltages are supplied from a power supply circuit 6 and (ii) wirings. It is therefore possible to prevent a decrease in aperture ratio of a display device which includes the optical sensor circuit 20.

Note that Embodiment 5 is not limited to the configuration in which the sensor output line Vom and the power supply line Vsm are provided as lines separated from the respective source lines S. Embodiment 5 can therefore employ a configuration in which (i) a source line S serves also as the sensor output line Vom and (ii) a source line S serves also as the power supply line Vsm, as with Embodiment 1.

The present invention is not limited to the embodiments, but can be altered by a skilled person in the art within the scope of the claims. An embodiment derived from a proper combination of technical means disclosed in respective different embodiments is also encompassed in the technical scope of the present invention.

In the optical sensor circuit of the present invention, it is preferable that the second transistor has (i) a drain connected with a first voltage control line, (ii) a gate connected with a second voltage control line, and (iii) a source connected with a drain of the first transistor; the first transistor has (i) a gate connected with a third voltage control line, (ii) the drain connected with the source of the second transistor; and (iii) a source connected with a fourth voltage control line; and each of the first through fourth voltage control lines being used to control the voltage to be generated at the connecting point.

According to the configuration, it is possible to set a sensor output voltage, which is obtained in response to received light with high intensity, to be higher than a sensor output voltage obtained in response to received light with low intensity, by setting electric potentials of the first through fourth voltage control lines to respective predetermined values. It is therefore possible to prevent an S/N value (D.R. value) from being decreased due to stray light caused by external light. This allows an improvement in reliability of the optical sensor circuit.

The optical sensor circuit of the present invention further includes: a third transistor; and a fourth transistor, the fourth transistor having (i) a gate connected with a readout control line, (ii) a drain connected with a sensor output line, and (iii) a source connected with a drain of the third transistor, the third transistor having (i) a gate connected with the connecting point, (ii) the drain connected with the source of the fourth transistor, and (iii) a source connected with a power supply line, a readout pulse for reading out the voltage generated at the connecting point being applied via the readout control line, and the voltage generated at the connecting point being outputted via the third transistor, the fourth transistor, and the sensor output line.

According to the configuration, when a readout pulse is applied to the readout control line, the fourth transistor starts a readout operation, and the voltage generated at the connecting point is outputted, as a sensor output voltage, form the drain of the fourth transistor. Note that the sensor output voltage corresponds to the voltage at the connecting point, i.e., corresponds to a voltage which is generated at the connecting point and varies depending on intensity of received light. It is therefore possible to detect the intensity of received light by outputting the sensor output voltage.

In the optical sensor circuit of the present invention, it is preferable that the fourth voltage control line serves also as the power supply line.

This makes it possible to reduce the number of power sources to be provided. It is therefore possible to prevent a decrease in aperture ratio of a display device including the optical sensor circuit.

In the optical sensor circuit of the present invention, it is preferable that the second voltage control line serves also as the third voltage control line.

This makes it possible to reduce the number of power sources to be provided. It is therefore possible to prevent a decrease in aperture ratio of a display device including the optical sensor circuit.

In order to attain the object, a display panel of the present invention includes the above described optical sensor circuit.

The display panel of the present invention further includes a plurality of gate lines; a plurality of source lines which intersect with the plurality of gate lines; and a plurality of picture elements provided at respective intersections of the plurality of gate lines and the plurality of source lines, the plurality of picture elements being arranged in a matrix manner.

In the display panel of the present invention, it is preferable that the optical sensor circuit is provided for each pixel which is made up of at least one picture element.

According to the configuration, in a touch panel for example, the optical sensor circuit is provided for each pixel which is made up of at least one picture element. This allows an improvement in accuracy of touch location detection.

In the display panel of the present invention, it is preferable that, in each of the optical sensor circuits, a sensor output line serves also as a corresponding one of the plurality of source lines.

This makes it possible to reduce the number of power sources to be provided. It is therefore possible to prevent a decrease in aperture ratio of a display device including the optical sensor circuit.

In the display panel of the present invention, it is preferable that, in each of the optical sensor circuits, a power supply line serves also as a corresponding one of the plurality of source lines.

This makes it possible to reduce the number of power sources to be provided. It is therefore possible to prevent a decrease in aperture ratio of a display device including the optical sensor circuit.

The display panel of the present invention preferably further includes, in each of the optical sensor circuits, a retention capacitor line for retaining a capacitor of a display element, the first voltage control line serving also as the retention capacitor line.

This makes it possible to reduce the number of power sources to be provided. It is therefore possible to prevent a decrease in aperture ratio of a display device including the optical sensor circuit.

The display panel of the present invention preferably further includes a color filter layer; and a filter for blocking visible light components, the filter being provided in a layer facing the first transistor, the layer and the color filter layer being juxtaposed to each other so as to constitute a single layer.

According to the configuration, visible light component among various lights contained in external light, which visible light component tends to become a noise, hardly enter the first transistor but infrared light enters the first transistor. As such, it is possible to carry out a stable sensing operation under various circumstances without being adversely affected by external circumstances (such as external light intensity) of the liquid crystal display device. For example, it is possible to improve reliability of a transistor having a light receiving layer made of a-Si, by blocking light (visible light) having a wavelength which causes large change in characteristic over time.

In the display panel of the present invention, it is preferable that the filter is made up of a color filter having three layers of RGB.

With the configuration, the filter can be concurrently formed with forming of the color filter layer. This allows a reduction in cost, as compared with a case where the filter and the color filter layer are made from respective different materials and in respective different processes.

In order to attain the object, a display device of the present invention includes the above described display panel.

### INDUSTRIAL APPLICABILITY

The present invention is suitably applicable to an electronic device including an optical sensor.

### REFERENCE SIGNS LIST

1: Display panel
2: Display scanning signal line driving circuit
3: Display data signal line driving circuit
4: Sensor scanning signal line driving circuit
5: Sensor readout circuit
6: Power supply circuit
7: Sensing image processing device
8: Display area
10: Liquid crystal display device
20: Optical sensor circuit
20a through 20d: TFT (fourth, third, second, and first transistors)
21: Display element driving circuit
22: TFT
23: Picture element electrode
30: Counter substrate
31: Insulating substrate
32: Polarizing plate
33: Color filter layer
34: Black matrix (light blocking member)
35: Visible light blocking filter
38: Backlight
40: Active matrix substrate
50: Liquid crystal layer
Cs: Retention capacitor line
E: Sensor scanning signal line
G: Gate line
S: Source line
PIX: Picture element
Prwn: Readout pulse
Vc1n through Vc4n: Node netB voltage control line (first through fourth voltage control line)
Vo: Sensor output line
Vrwn: Readout control line
Vs: Power supply line
netB: Node

1. An optical sensor circuit comprising:
a first transistor; and
a second transistor,
the first transistor being connected in series with the second transistor,
the first transistor being configured to receive light,
a light blocking member being provided so as to face the second transistor, and
a voltage, which is generated at a connecting point of the first transistor and the second transistor, varying depending on intensity of light received via the first transistor.

2. The optical sensor circuit as set forth in claim 1, wherein:
the second transistor has (i) a drain connected with a first voltage control line, (ii) a gate connected with a second voltage control line, and (iii) a source connected with a drain of the first transistor;
the first transistor has (i) a gate connected with a third voltage control line, (ii) the drain connected with the source of the second transistor; and (iii) a source connected with a fourth voltage control line; and
each of the first through fourth voltage control lines being used to control the voltage to be generated at the connecting point.

3. An optical sensor circuit as set forth in claim 2, further comprising:
a third transistor; and
a fourth transistor,
the fourth transistor having (i) a gate connected with a readout control line, (ii) a drain connected with a sensor output line, and (iii) a source connected with a drain of the third transistor,
the third transistor having (i) a gate connected with the connecting point, (ii) the drain connected with the source of the fourth transistor, and (iii) a source connected with a power supply line,
a readout pulse for reading out the voltage generated at the connecting point being applied via the readout control line, and
the voltage generated at the connecting point being outputted via the third transistor, the fourth transistor, and the sensor output line.

4. The optical sensor circuit as set forth in claim 3, wherein:
the fourth voltage control line serves also as the power supply line.

5. The optical sensor circuit as set forth in claim 3, wherein:
the second voltage control line serves also as the third voltage control line.

6. A display panel comprising an optical sensor circuit recited in claim 1.

7. A display panel comprising an optical sensor circuit recited in claim 3.

8. A display panel as set forth in claim 7, further comprising:
a plurality of gate lines;
a plurality of source lines which intersect with the plurality of gate lines; and
a plurality of picture elements provided at respective intersections of the plurality of gate lines and the plurality of source lines, the plurality of picture elements being arranged in a matrix manner.

9. The display panel as set forth in claim 8, wherein:
the optical sensor circuit is provided for each pixel which is made up of at least one picture element.

10. The display panel as set forth in claim 8, wherein:
in each of the optical sensor circuits, a sensor output line serves also as a corresponding one of the plurality of source lines.

11. The display panel as set forth in claim 8, wherein:
in each of the optical sensor circuits, a power supply line serves also as a corresponding one of the plurality of source lines.

12. A display panel as set forth in claim 7, further comprising in each of the optical sensor circuits:
a retention capacitor line for retaining a capacitor of a display element,
the first voltage control line serving also as the retention capacitor line.

13. A display panel as set forth in claim 6, further comprising:
a color filter layer; and
a filter for blocking visible light components, the filter being provided in a layer facing the first transistor, the layer and the color filter layer being juxtaposed to each other so as to constitute a single layer.

14. The display panel as set forth in claim 13, wherein:
the filter is made up of a color filter having three layers of RGB.

15. A display device comprising a display panel recited in claim 6.

16. A method for driving an optical sensor circuit,
said optical sensor circuit including a first transistor, a second transistor, a third transistor, and a fourth transistor,
the first transistor being connected in series with the second transistor,
the first transistor being configured to receive light,
a light blocking member being provided so as to face the second transistor,
the fourth transistor having (i) a gate connected with a readout control line, (ii) a drain connected with a sensor output line, and (iii) a source connected with a drain of the third transistor,
the third transistor having (i) a gate connected with a connecting point of the first transistor and the second transistor, (ii) the drain connected with the source of the fourth transistor, and (iii) a source connected with a power supply line,
the second transistor having (i) a drain connected with a first voltage control line, (ii) a gate connected with a second voltage control line, and (iii) a source connected with a drain of the first transistor,
the first transistor having (i) a gate connected with a third voltage control line, (ii) the drain connected with the source of the second transistor, and (iii) a source connected with a fourth voltage control line, and
a voltage, which is generated at the connecting point, being controlled by use of the first through fourth voltage control lines,
said method comprising the steps of:
(a) applying voltages to the respective first through fourth voltage control lines;
(b) applying a readout pulse to the readout control line connected with the gate of the fourth transistor during the step (a); and
(c) causing a voltage, which has generated in response to light received by the first transistor, to be outputted via the third transistor, the fourth transistor, and the sensor output line, the voltage varying depending on intensity of the light received via the first transistor.
